(19) United States
(12) Patent Application Publication
(10) Pub. No.: US 2011/0123925 A1
(43) Pub. Date: May 26, 2011

(54) POLYMER FOR PROTECTIVE LAYER OF RESIST, AND POLYMER COMPOSITION INCLUDING THE SAME

(76) Inventors: Sang-Geun YUN, Uiwang-si (KR); Sang-Jun Choi, Uiwang-si (KR); Seung-Jib Choi, Uiwang-si (KR); Sung-Jae Lee, Uiwang-si (KR)

(21) Appl. No.: 12/950,369

(22) Filed: Nov. 19, 2010

(30) Foreign Application Priority Data
Nov. 25, 2009 (KR) 10-2009-0114808

(51) Int. Cl. G03F 7/004; G03F 7/20; C08F 220/28; C09D 127/12

(52) U.S. Cl. 430/270.1; 430/322; 526/245; 524/544

(57) ABSTRACT

A polymer includes a first repeating unit represented by the following Chemical Formula 1, and a second repeating unit including at least one repeating unit represented by the following Chemical Formulae 2 to 6.

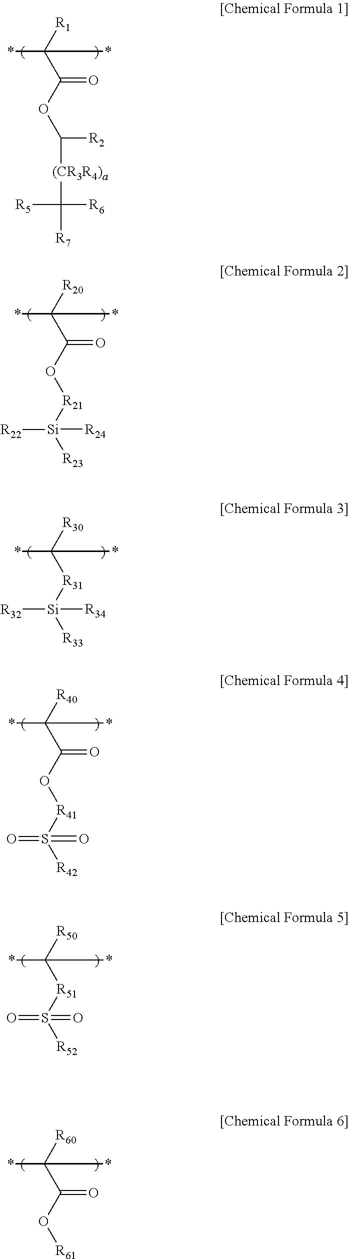

### BACKGROUND

1. Field

Embodiments relate to a polymer for a resist protective layer and a resist protective layer composition including the same.

2. Description of the Related Art

A finer photosensitive resin composition pattern is increasingly required for high integration of a semiconductor chip, as the semiconductor industry is continuing to develop. A finer pattern for higher integration needs lithography technology that enables fine processes of a line width of 0.10 μm or less. Particularly, a shorter X-ray is being researched for such use. The radioactive ray with a short wavelength may include, for example, a bright-line spectrum of a mercury lamp, extreme ultraviolet (UV) representatively including an excimer laser, X-ray, an electron beam (e-beam), and the like, and in particular, a KrF excimer laser having a wavelength of 248 nm, or an ArF excimer laser having a wavelength of 193 nm.

This excimer laser may work very well with a resist (hereinafter referred to as a “chemically amplified resist”) using a chemical-amplifying effect of a component with an acid-labile functional group and a component (hereinafter referred to as an “acid generator”) producing acid due to x-ray radiation (hereinafter referred to as “exposure”). The chemically amplified resist may include, for example, a resist including a resin including a t-butylester group connected to carboxylic acid or a t-butylcarbonate group connected to phenol and an acid generator.

When this resist forms a resist layer, the t-butylester group or the t-butylcarbonate group may be dissociated from the resin of the resist layer by acid generated during the exposure. Thus, the resin may include an acidic group including a carboxyl group or a phenolic hydroxyl group.

As a result, the exposed region may be easily dissolved in an alkali development solution. Recently, since a much finer pattern with a line width of 45 nm is required, a method of developing an exposure apparatus with a shorter light source wavelength and increasing the numerical aperture (NA) of a lens has been researched. However, the former method of developing an exposure apparatus with a shorter light source wavelength needs an expensive new exposure apparatus, causing an economic problem, and the latter method of increasing the numerical apertures of the lens has a trade-off problem between resolution and depth of focus (DOF).

In other words, if the resolution is increased, the depth of focus may be deteriorated. Accordingly, a liquid immersion lithography method has been recently reported in order to solve the problem. The liquid immersion lithography method performs an exposure process by disposing a liquid immersion lithography medium (liquid for liquid immersion lithography) with a predetermined thickness between a lens and a resist layer. The liquid immersion lithography medium may be a medium such as pure water, a fluorine-based inert liquid, or the like.

This method has an advantage of accomplishing high resolution without deteriorating depth of focus like using a light source with a short wavelength or a lens with high numerical apertures, since this method fills the space of an exposure apparatus with a liquid with a larger refractive index (n) such as pure water and the like instead of an inert gas such as air, nitrogen, or the like, even though it uses a light source with the same exposure wavelength as a conventional method. In addition, this immersion lithography method has been paid much attention, since it makes it possible to form an excellent resist pattern having high resolution and an excellent depth of focus with a low cost, even though it uses a presently-used lens.

### SUMMARY

It is a feature of an embodiment to provide a polymer for a resist protective layer having excellent productivity and fewer defects by regulating receding and advancing angles.

It is another feature of an embodiment to provide a resist protective layer composition including the polymer.

At least one of the above and other features and advantages may be realized by providing a polymer for a resist protective layer, including:

a first repeating unit represented by the following Chemical Formula 1; and

a second repeating unit including at least one repeating unit represented by the following Chemical Formulae 2 to 6:

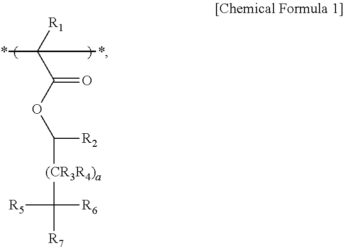

wherein, in Chemical Formula 1,

R₁ is hydrogen, fluorine, or a substituted or unsubstituted alkyl group,

R₂ is hydrogen or a substituted or unsubstituted alkyl group,

R₃ and R₄ are the same or different, and are hydrogen, fluorine, or a substituted or unsubstituted alkyl group,

R₅ to R₆ are the same or different, and are hydrogen or a fluoroalkyl group, provided that at least one R₅ to R₆ is —(CH₂)ₙ—CF₃ (n is 0 to 10),

R₇ is OH or SH, and

a is an integer ranging from 0 to 10,

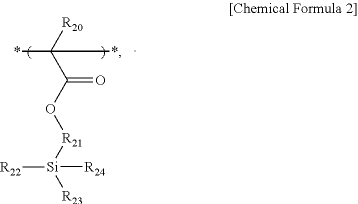

wherein, in Chemical Formula 2,

R₂₀ is hydrogen, fluorine, or a substituted or unsubstituted alkyl group,

R₂₁ is a single bond or an alkylene group, and

R₂₂ to R₂₄ are the same or different, and are hydrogen, fluorine, a substituted or unsubstituted alkyl group, OR₂₅, or OR₂₆OH, wherein R₂₅ and R₂₆ are the same or different, and are hydrogen, fluorine, a substituted or unsubstituted alkyl group, or Si(R₂₇)₃, wherein R₂₇ is hydrogen, fluorine, or a substituted or unsubstituted alkyl group,

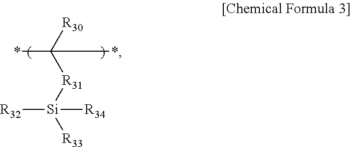

wherein, in Chemical Formula 3,

R₃₀ is hydrogen, fluorine, or a substituted or unsubstituted alkyl group,

R₃₁ is a single bond, or a substituted or unsubstituted alkylene group, and

R₃₂ to R₃₄ are the same or different, and are hydrogen, fluorine, a substituted or unsubstituted alkyl group, or OR₃₅, wherein R₃₅ is hydrogen, fluorine, a substituted or unsubstituted alkyl group, or Si(R₃₆)₃, wherein R₃₆ is hydrogen, fluorine, or a substituted or unsubstituted alkyl group,

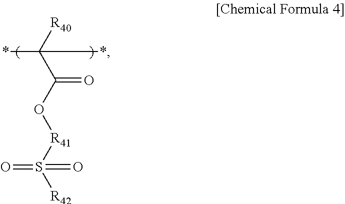

wherein, in Chemical Formula 4,

R₄₀ is hydrogen, fluorine, or a substituted or unsubstituted alkyl group,

R₄₁ is a single bond, or an alkylene group where carbon is partially replaced or not replaced with nitrogen, and

R₄₂ is a substituted or unsubstituted alkyl group or an OH group,

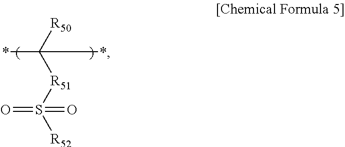

wherein, in Chemical Formula 5,

R₅₀ is hydrogen, fluorine, or a substituted or unsubstituted alkyl group,

R₅₁ is a single bond, or a linear, branched, or cyclic alkylene group where carbon is partially replaced or not replaced with nitrogen, and

R₅₂ is a substituted or unsubstituted alkyl group or an OH group,

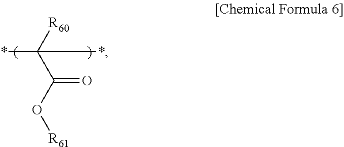

wherein, in Chemical Formula 6,

R₆₀ is hydrogen, fluorine, or a substituted or unsubstituted alkyl group, and

R₆₁ is hydrogen, a substituted or unsubstituted alkyl group, or a hydroxy alkyl group.

The first repeating unit and the second repeating unit may be present in the polymer at a ratio of about 95:5 to about 30:70 mol %.

The polymer may have a weight average molecular weight ranging from about 3,000 to about 50,000.

The second repeating unit may include at least one repeating unit represented by Chemical Formula 2, the at least one repeating unit represented by Chemical Formula 2 being selected from the group represented by the following Chemical Formulae 2-1 to 2-8:

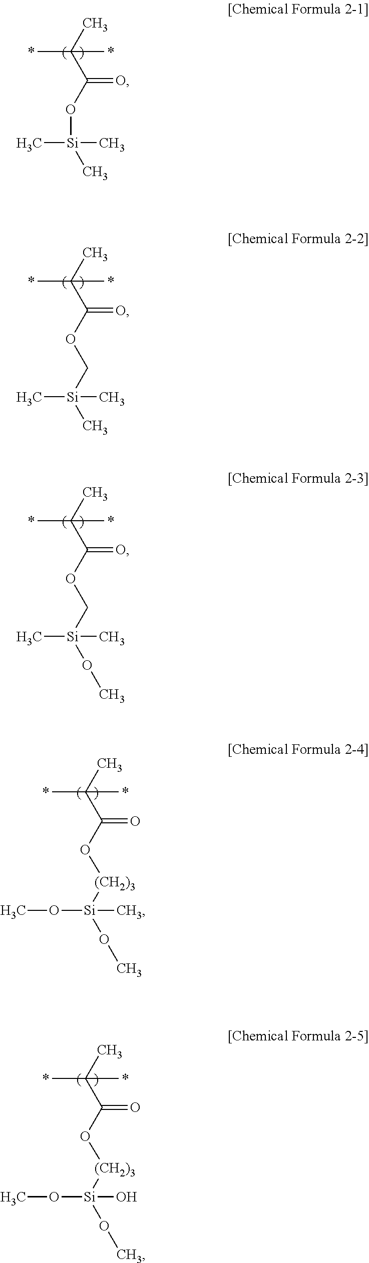

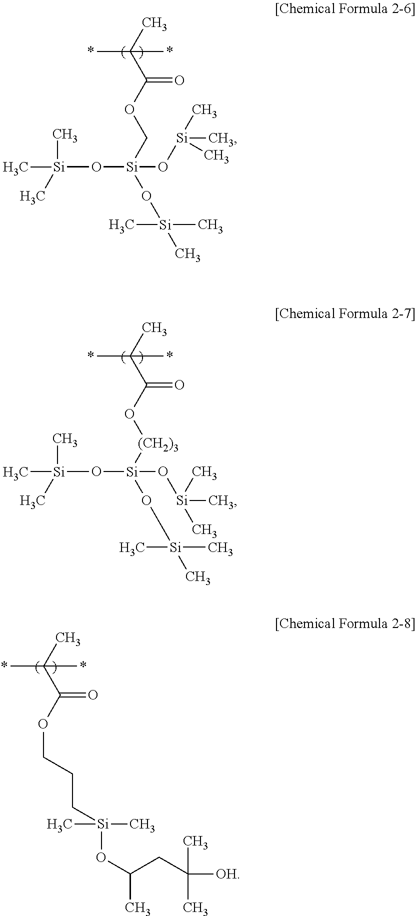

The second repeating unit may include at least one repeating unit represented by Chemical Formula 3, the at least one repeating unit represented by Chemical Formula 3 being represented by the following Chemical Formula 3-1:

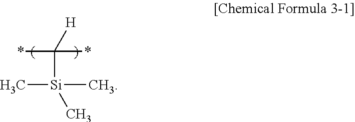

The second repeating unit may include at least one repeating unit represented by Chemical Formula 4, the at least one repeating unit represented by Chemical Formula 4 being selected from the group represented by the following Chemical Formulae 4-1 to 4-3:

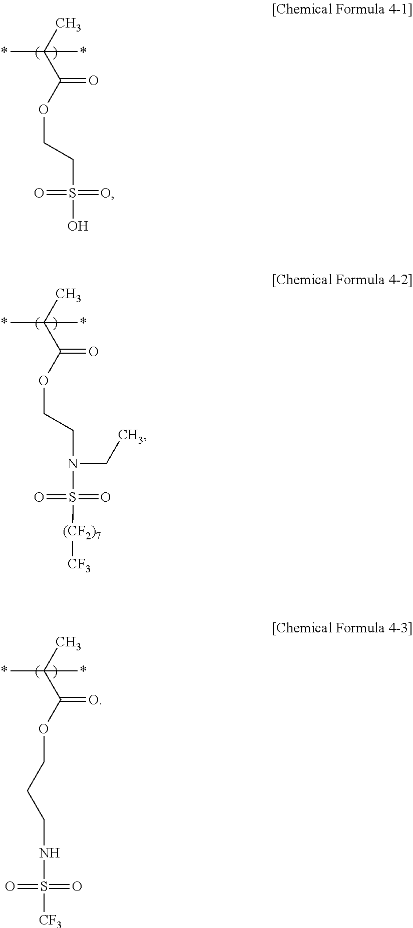

The second repeating unit may include at least one repeating unit represented by Chemical Formula 5, the at least one repeating unit represented by Chemical Formula 5 being selected from the group represented by the following Chemical Formulae 5-1 to 5-2:

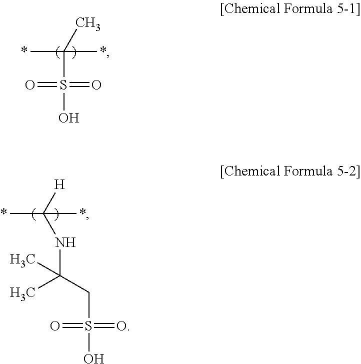

The second repeating unit may include at least one repeating unit represented by Chemical Formula 6, the at least one repeating unit represented by Chemical Formula 6 being selected from the group represented by the following Chemical Formulae 6-1 to 6-3:

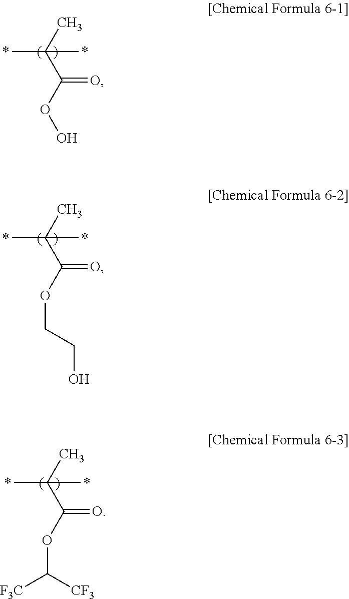

At least one of the above and other features and advantages may also be realized by providing a resist protective layer composition, including a polymer according to an embodiment, and an organic solvent.

In the composition, the polymer may be included in an amount of about 1 to about 30 parts by weight based on 100 parts by weight of the organic solvent.

The composition may further include a photoacid generator.

At least one of the above and other features and advantages may also be realized by providing a method of forming a pattern, the method including providing a photosensitive resin composition layer on a substrate, providing a protective layer on the photosensitive resin composition layer using a protective layer composition according to an embodiment, and forming a pattern using liquid immersion lithography using the photosensitive resin composition layer having the protective layer thereon.

### DETAILED DESCRIPTION

Korean Patent Application No. 10-2009-0114808, filed on Nov. 25, 2009, in the Korean Intellectual Property Office, and entitled: “Polymer for Protective Layer of Resist, and Polymer Composition Including Same,” is incorporated by reference herein in its entirety.

Example embodiments will now be described more fully hereinafter; however, they may be embodied in different forms and should not be construed as limited to the embodiments set forth herein. Rather, these embodiments are provided so that this disclosure will be thorough and complete, and will fully convey the scope of the invention to those skilled in the art.

As used herein, when a definition is not otherwise provided, the term “alkyl group” may refer to a C₁₋₁₀ linear or branched alkyl group, “alkylene group” may refer to a C₁₋₁₀ linear, branched, or cyclic alkylene group, and “hydroxyalkyl group” may refer to a C₁₋₁₀ hydroxyalkyl group.

As used herein, when a definition is not otherwise provided, the term “substituted” may refer to a functional group substituted with at least one selected from the group of a halogen (F, Cl, Br, or I), a hydroxyl group, a nitro group, a cyano group, an amino group such as —NH₂, —NH(R), —N(R′″)(R″″), where R′″ and R″″ are independently a C₁₋₁₀ alkyl group, an amidino group, a hydrazine group or hydrazone group, a carboxyl group, a silane group, a substituted or unsubstituted C₁₋₁₀ alkyl group, a substituted or unsubstituted C₆₋₂₀ aryl group, a substituted or unsubstituted C₃₋₂₀ cycloalkyl group, a substituted or unsubstituted C₃₋₂₀ heteroaryl group, and a substituted or unsubstituted C₂₋₂₀ heterocycloalkyl group instead of at least one hydrogen.

The term “substituted” may refer to one substituted with a halogen and specifically fluorine.

As used herein, when a definition is not otherwise provided, the term “hetero” may refer to one including at least one heteroatom selected from the group of N, O, S, and P.

Herein, Markush groups, if any, are identified by the closed language “selected from the group consisting of.” Hence, the language “the group of,” as used herein, does not denote a Markush group.

An embodiment relates to a polymer for a resist protective layer. According to an embodiment, a resist protective layer may be disposed on the surface of a resist layer, so that the resist layer does not directly contact a liquid immersion lithography medium, e.g., water, in an immersion lithography method, when forming a fine pattern. The resist protective layer may be referred to as a top coat. The resist protective layer may be very hydrophobic, and may exhibit a high receding angle against water and excellent solubility in an alkali development solution.

According to an embodiment, the polymer may satisfy all these characteristics. In particular, when the polymer is used to form a resist protective layer, the resist protective layer may provide a high receding angle of 70° or higher against water. The protective layer may be good for draining water. Thus, it may not leave a water mark.

An embodiment relates to a polymer including a first repeating unit represented by the following Chemical Formula 1 and a second repeating unit including at least one repeating unit represented by the following Chemical Formulae 2 to 6. When the second repeating unit includes one of the following Chemical Formulae 2 to 6, it may be a binary copolymer. When the second repeating unit includes two of the following Chemical Formulae 2 to 6, it may be a ternary copolymer or terpolymer.

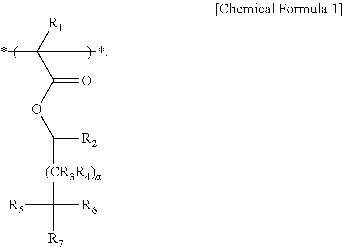

In Chemical Formula 1,

R₁ may be hydrogen, fluorine, or a substituted or unsubstituted alkyl group,

R₂ may be hydrogen, or a substituted or unsubstituted alkyl group,

R₃ and R₄ are the same or different, and are hydrogen, fluorine, or a substituted or unsubstituted alkyl group,

R₅ to R₆ may be the same or different, and may be hydrogen or a fluoroalkyl group, and at least one of R₅ to R₆ may be —(CH₂)ₙ—CF₃, where n may be an integer ranging from 0 to 10,

R₇ may be OH or SH, and

a may be an integer ranging from 0 to 10.

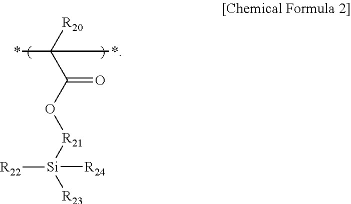

In Chemical Formula 2,

R₂₀ may be hydrogen, fluorine, or a substituted or unsubstituted alkyl group,

R₂₁ may be a single bond or an alkylene group, and

R₂₂ to R₂₄ may be the same or different, and may be hydrogen, fluorine, a substituted or unsubstituted alkyl group, OR₂₅, or OR₂₆OH, wherein R₂₅ and R₂₆ may be the same or different, and may be hydrogen, fluorine, a substituted or unsubstituted alkyl group, or Si(R₂₇)₃, wherein R₂₇ may be hydrogen, fluorine, or a substituted or unsubstituted alkyl group.

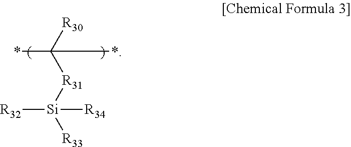

In Chemical Formula 3,

R₃₀ may be hydrogen, fluorine, a substituted or unsubstituted alkyl group,

R₃₁ may be a single bond, or a substituted or unsubstituted alkylene group, and

R₃₂ to R₃₄ may be the same or different, and may be hydrogen, fluorine, a substituted or unsubstituted alkyl group, or OR₃₅, wherein R₃₅ may be hydrogen, fluorine, a substituted or unsubstituted alkyl group, or Si(R₃₆)₃, wherein R₃₆ may be hydrogen, fluorine, or a substituted or unsubstituted alkyl group.

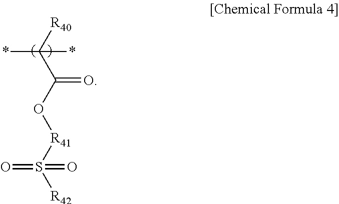

In Chemical Formula 4,

R₄₀ may be hydrogen, fluorine, or a substituted or unsubstituted alkyl group,

R₄₁ may be a single bond, or an alkylene group where carbon is partially replaced or not replaced with nitrogen, and

R₄₂ may be a substituted or unsubstituted alkyl group or an OH group.

Where part of carbon is replaced or not replaced with nitrogen, the moiety may be an aminoalkylene (see, e.g., Formulae 4-2 and 4-3, below) or an alkylene, respectively.

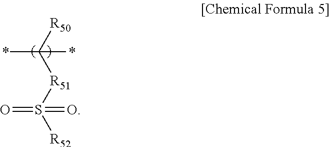

In Chemical Formula 5,

R₅₀ may be hydrogen, fluorine, or a substituted or unsubstituted alkyl group,

R₅₁ may be a single bond, or a linear, branched, or cyclic alkylene group where carbon is partially replaced or not replaced with nitrogen, and

R₅₂ may be a substituted or unsubstituted alkyl group or an OH group.

Where part of carbon is replaced or not replaced with nitrogen, the moiety may be an aminoalkylene (see, e.g., Formula 5-2, below) or an alkylene, respectively.

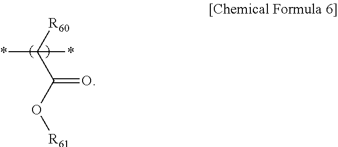

In Chemical Formula 6,

R₆₀ may be hydrogen, fluorine, or a substituted or unsubstituted alkyl group, and

R₆₁ may be hydrogen, a substituted or unsubstituted alkyl group, or a hydroxy alkyl group.

A compound represented by the above Chemical Formula 1 may include an OH or SH group at R₇. Thus, it may be very well dissolved in an alkali development solution. In addition, a compound represented by the above Chemical Formula 1 may include at least one fluorine, an electron-withdrawing group, at R₅ to R₆. Thus, the OH or SH group at R₇ may be more acidic and thus better dissolved in an alkali development solution.

An example of the first repeating unit represented by the above Chemical Formula 1 may have the following Chemical Formula 1-1.

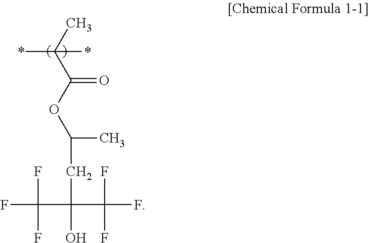

The second repeating unit represented by the above Chemical Formula 2 may have the following Chemical Formulae 2-1 to 2-8.

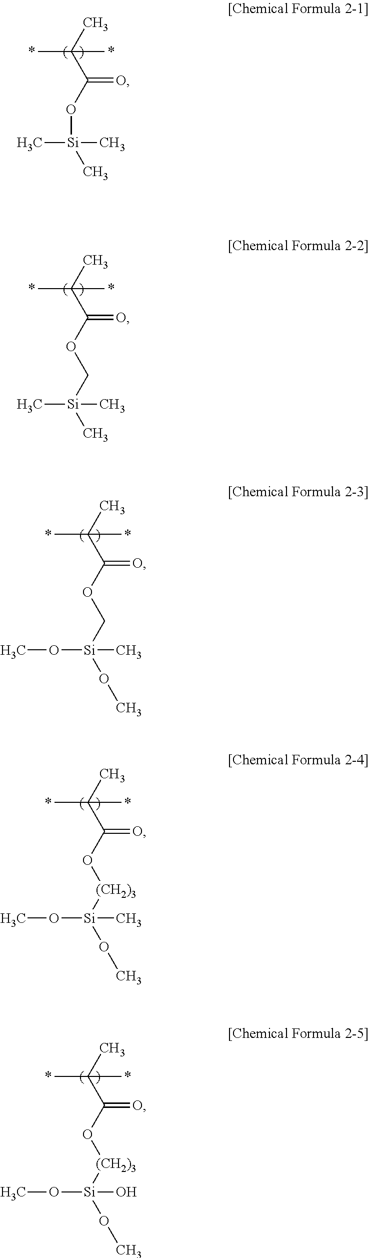

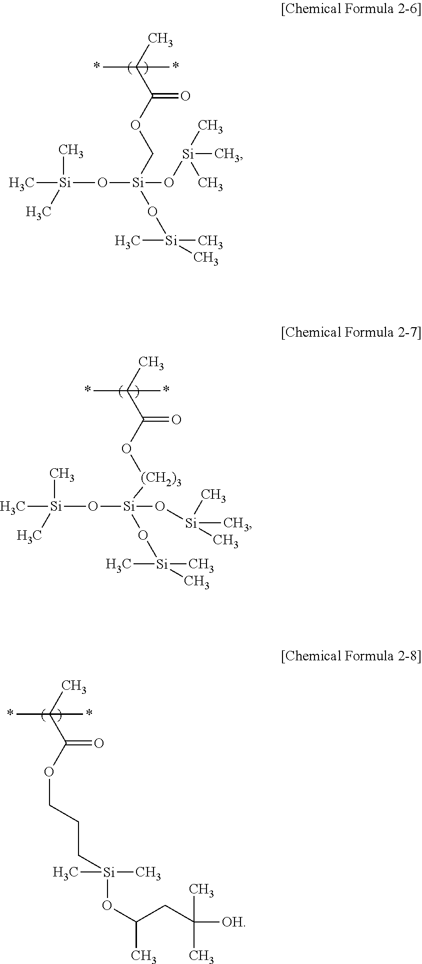

The second repeating unit represented by the above Chemical Formula 3 may have the following Chemical Formula 3-1.

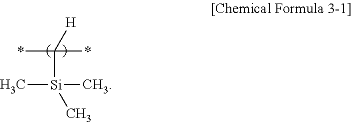

The second repeating unit represented by the above Chemical Formula 4 may have the following Chemical Formulae 4-1 to 4-3.

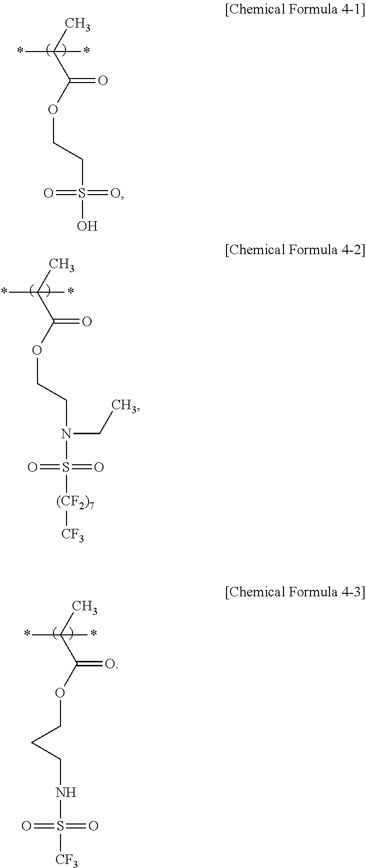

The second repeating unit represented by the above Chemical Formula 5 may have the following Chemical Formulae 5-1 to 5-2.

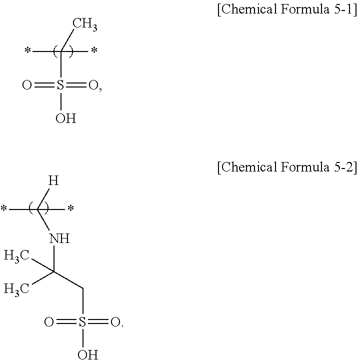

The second repeating unit represented by the above Chemical Formula 6 may have the following Chemical Formulae 6-1 to 6-3.

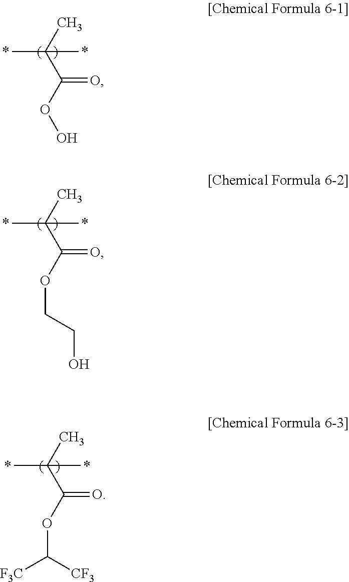

A polymer according to an embodiment may include the first and second repeating units in a ratio of about 95:5 to about 30:70 mol %, or about 90:10 to about 55:45 mol % in another embodiment. When the first and second repeating units are present in the polymer in the stated range, they may have an effect of increasing a receding angle to higher than 70° and decreasing an advancing contact angle to less than 100°, and the polymer may also be very well dissolved in an alkali development solution, accelerating a developing rate.

A polymer according to an embodiment may have a weight average molecular weight of about 3,000 to about 50,000, or about 4,000 to about 20,000 in another embodiment. When the polymer has a weight average molecular weight within the range, it may have high solubility in an alkali solution and a high receding angle against water.

Another embodiment provides a resist protective layer composition including the polymer and an organic solvent.

The resist protective layer composition may include the polymer in an amount of about 1 to about 30 parts by weight based on 100 parts by weight of the organic solvent. When the polymer is included within the range, the resist protective layer composition may be coated to have a desired thickness.

The organic solvent is not particularly limited. The organic solvent may be selected to avoid dissolving a resist layer.

Examples of the organic solvent may include a non-polar solvent such as higher alcohols having more than 4 carbons, toluene, xylene, anisole, hexane, cyclohexane, decane, an ether-based compound, and the like, and also a fluorine-based solvent.

Examples of the ether-based compound include di-n-butylether, diisobutylether, diisopentylether, di-n-pentylether, methylcyclopentylether, methylcyclohexylether, di-n-butylether, di-sec-butylether, diisopentylether, di-sec-pentylether, di-t-amylether, isoamylether, di-n-hexylether, and the like.

Examples of the alcohol-based compound include 1-butanol, 2-butanol, isobutanol, tert-butanol, 1-pentenol, 2-pentenol, 3-pentenol, tert-amylalcohol, neopentenol, 2-methyl-1-butanol, 3-methyl-1-butanol, 3-methyl-3-pentenol, cyclopentenol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentenol, 2-methyl-2-pentenol, 2-methyl-3-pentenol, 3-methyl-1-pentenol, 3-methyl-2-pentenol, 3-methyl-3-pentenol, 4-methyl-1-pentenol, 4-methyl-2-pentenol, 4-methyl-3-pentenol, cyclohexanol, and the like.

Examples of the fluorine-based solvent include 2-fluoroanisole, 4-fluoroanisole, 2,3-difluoroanisole, 2,4-difluoroanisole, 2,5-difluoroanisole, 5,8-difluoro-1,4-benzodioxane, 2,3-difluorobenzylalcohol, 1,3-difluoro-2-propanol, 2′,4′-difluoropropinophenone, 2,4-difluorotoluene, trifluoroacetaldehydeethylhemiacetal, trifluoroacetamide, trifluoroethanol, 2,2,2-trifluoroethylbutyrate, ethylheptafluorobutyrate, ethylheptafluorobutylacetate, ethyl-3-hydroxy-4,4,4-trifluorobutyrate, ethyl-2-methyl-4,4,4-trifluoroacetoacetate, ethylpentafluorobenzoate, ethylpentafluoropropionate, ethylpentafluoropropylacetate, ethylperfluorooctanoate, ethyl-4,4,4-trifluoroacetoacetate, ethyl-4,4,4-trifluorobutyrate, ethyl-4,4,4-trifluorocrotonate, ethyltrifluorosulfonate, ethyl-3-(trifluoromethyl)butyrate, ethyltrifluoropyruvate, S-ethyltrifluoroacetate, fluorocyclohexane, 2,2,3,3,4,4,4-heptafluoro-1-butanol, 1,1,1,2,2,3,3-heptafluoro-7,7-dimethyl-4,6-octanedione, 1,1,1,3,5,5,5-heptafluoropentane-2,4-dione, 3,3,4,4,5,5,5-heptafluoro-2-pentenol, 3,3,4,4,5,5,5-heptafluoro-2-pentanone, isopropyl 4,4,4-trifluoroacetoacetate, methylperfluorodenanoate, methylperfluoro(2-methyl-3-oxahexanoate), methylperfluoronanoate, methylperfluorooctanoate, methyl-2,3,3,3-tetrafluoropropionate, methyltrifluoroacetoacetate, 1,1,1,2,2,6,6,6-octafluoro-2,4-hexanedione, 2,2,3,3,4,4,5,5-octafluoro-1-pentenol, 1H,1H,2H,2H-perfluoro-1-decanol, perfluoro(2,5-dimethyl-3,6-dioxane anionic acid) methyl ester, 2H-perfluoro-5-methyl-3,6-dioxanonane, 1H,1H,2H,2H-perfluorooctanol, 2H-perfluoro-5,8,11,14-tetramethyl-3,6,9,12,15-pentaoxaoctadecane, perfluorotributylamine, perfluorotrihexylamine, perfluoro-2,5,8-trimethyl-3,6,9-trioxadodecanoic acid methyl ester, perfluorotripentylamine, perfluorotripropylamine, 1H,1H,2H,3H,3H-perfluoroundecane-1,2-diol, trifluorobutanol, 1,1,1-trifluoro-5-methyl-2,4-hexanedione, 1,1,1-trifluoro-2-propanol, 3,3,3-trifluoro-1-propanol, 1,1,1-trifluoro-2-propylacetate, perfluorobutyltetrahydrofuran, perfluoro(butyltetrahydrofuran), perfluoro decalin, perfluoro(1,2-dimethylcyclohexane), perfluoro(1,3-dimethylcyclohexane), propyleneglycoltrifluoromethyletheracetate, propyleneglycolmethylethertrifluoromethylacetate, trifluoromethylacetic acid butyl ester, 3-trifluoromethoxypropionic acid methyl ester, perfluorocyclohexanone, propyleneglycoltrifluoromethylether, trifluoroacetic acid butyl ester, 1,1,1-trifluoro-5,5-dimethyl-2,4-hexanedione, 1,1,1,3,3,3-hexafluoro-2-propanol, 1,1,1,3,3,3-hexafluoro-2-methyl-2-propanol, 2,2,3,4,4,4-hexafluoro-1-butanol, 2-trifluoromethyl-2-propanol, 2,2,3,3-tetrafluoro-1-propanol, 3,3,3-trifluoro-1-propanol, 4,4,4-trifluoro-1-butanol, and the like.

The resist protective layer composition according to an embodiment may further include a photoacid generator (PAG). The photoacid generator may be used by adjusting the amount thereof in a desirable range.

The photoacid generator may be selected from the group of an inorganic onium salt, organic sulfonate, and mixtures thereof. Examples of the photoacid generator include sulfonate or iodonium salt selected from the group of a triarylsulfonium salt, a diaryl iodonium salt, sulfonate, or mixtures thereof In an embodiment, the photoacid generator may include triarylsulfonium triflate, diaryliodonium triflate, triarylsulfonium nonaflate, diaryliodonium nonaflate, succinimidyl triflate, 2,6-dinitrobenzyl sulfonate, or mixtures thereof.

A method of forming a pattern according to another embodiment includes providing a photosensitive resin composition layer on a substrate, providing a protective layer on the photosensitive resin composition layer using the protective layer composition, and forming a pattern using liquid immersion lithography.

Hereinafter, a method of forming a pattern will be described in detail.

First, a photosensitive resin composition layer may be disposed on a substrate.

The substrate may include a silicon substrate, e.g., a wafer. The photosensitive resin composition layer may be disposed using a common method of coating a photosensitive resist composition and firing it. Thus, further details of coating the photosensitive resist are not described here. A resist resin included in the photosensitive resist composition may have no particular limit, and may be either positive or negative.

On the photosensitive resin composition layer, a protective layer may be disposed by coating a protective layer composition according to an embodiment. Here, the coating process may be performed using a common method such as a spin coating method.

The protective layer may be about 40 to about 45 nm thick.

Next, an exposure process may be performed using a liquid immersion lithography method. The liquid immersion lithography method may be performed by inserting a liquid between the protective layer and projecting lens. Here, an exposure light source may have a wavelength ranging from about 180 to about 250 nm, for example, ArF, KrF, EUV (extreme UV), E-beam, or the like, and the liquid may include water.

When the exposure is complete, the protective layer may be heat-treated for a chemical reaction in an exposure region. The heat-treatment is performed at a temperature ranging from about 90 to 120° C. for about 60 to 90 seconds.

Then, the resulting product may be developed. The development may be performed using an alkali aqueous solution. The alkali aqueous solution may include a tetramethyl ammonium hydroxide (TMAH) aqueous solution. When an ArF excimer laser is used as an exposure light source, a 40 to 100 nm line and space pattern may be formed in a dose ranging from about 5 to about 30 mJ/cm².

The development may selectively remove the resist protective layer, since the resist protective layer can be dissolved in an alkali solution.

Hereinafter, embodiments are described in more detail with reference to examples. The following Examples and Comparative Example are provided in order to set forth particular details of one or more embodiments. However, it will be understood that the embodiments are not limited to the particular details described. Further, the Comparative Example is set forth to highlight certain characteristics of certain embodiments, and is not to be construed as either limiting the scope of the invention as exemplified in the Examples or as necessarily being outside the scope of the invention in every respect.

### EXAMPLES 1 TO 22

A first monomer (a monomer for a first repeating unit) provided as shown in the following Table 1 and second and third monomers (monomers for a second repeating unit) were put in a beaker according to the given mol % ratio and dissolved in an isopropyl alcohol (IPA) organic solvent, which was three times as much as the entire weight of the monomers. Next, 10 mmol of dimethyl-2,2′-azobis(2-methylpropionate) (V601, Wako Chemicals Co.) as a polymerization initiator was added to the solution. The resulting mixture was polymerized at 72° C. for about 6 hours. Here, the monomers and the polymerization initiator were respectively included in an amount of 88 wt % and 12 wt %.

When the polymerization was complete, the isopropyl alcohol solvent was distilled under reduced pressure and removed. The acquired product was dissolved in methanol, which was three times as much as the entire weight of the monomers, and hexane, which was seven times as much as the entire weight of the monomers, was added thereto. The resulting mixture was extracted. When separated into upper and lower layers, the lower layer was put into a round-bottomed flask and distilled under reduced pressure.

The resulting product was dried in a 50° C. vacuum oven for about 24 hours, preparing a desired polymer (average yield: 80 to 95%).

The polymers according to Examples 1 to 22 and Comparative Example 1 were measured regarding weight average molecular weight by using GPC (gel permeation chromatography) equipment made by Waters Co. The polymers of Examples 1 to 22 all had a weight average molecular weight ranging from about 11 k±0.2 k, but the polymer of Comparative Example 1 had a weight average molecular weight of about 10,500.

TABLE 1

| | First repeating | Second | | | | |
|---|---|---|---|---|---|---|
| | unit | repeating unit | | Mole ratio | | |
| | First | Second | Third | First | Second | Third |
| | monomer | monomer | monomer | monomer | monomer | monomer |
| Ex. 1 | Chem. Form. | Chem. Form. 2-4a | — | 95 | 5 | — |
| | 1-1a (HFPMA) | (P2) | | | | |
| Ex. 2 | Chem. Form. | Chem. Form. 2-5a | — | 95 | 5 | — |
| | 1-1a (HFPMA) | (P2OH) | | | | |
| Ex. 3 | Chem. Form. | Chem. Form. 2-3a | — | 95 | 5 | — |
| | 1-1a (HFPMA) | (M2) | | | | |
| Ex. 4 | Chem. Form. | Chem. Form. 2-6a | — | 95 | 5 | — |
| | 1-1a (HFPMA) | (M3) | | | | |
| Ex. 5 | Chem. Form. | Chem. Form. 2-3a | — | 97 | 3 | — |
| | 1-1a (HFPMA) | (M2) | | | | |
| Ex. 6 | Chem. Form. | Chem. Form. 4-3a | — | 95 | 5 | — |
| | 1-1a (HFPMA) | (SA3) | | | | |
| Ex. 7 | Chem. Form. | Chem. Form. 2-8a | — | 95 | 5 | — |
| | 1-1a (HFPMA) | (HFAP) | | | | |
| Ex. 8 | Chem. Form. | Chem. Form. 2-3a | Chem. Form. | 90 | 5 | 5 |
| | 1-1a (HFPMA) | (M2) | 4-3a (SA3) | | | |
| Ex. 9 | Chem. Form. | Chem. Form. 2-4a | — | 97 | 3 | — |
| | 1-1a (HFPMA) | (P2) | | | | |
| Ex. 10 | Chem. Form. | Chem. Form. 2-4a | — | 97 | 3 | — |
| | 1-1a (HFPMA) | (P2) | | | | |
| Ex. 11 | Chem. Form. | Chem. Form. 2-4a | — | 93 | 7 | — |
| | 1-1a (HFPMA) | (P2) | | | | |
| Ex. 12 | Chem. Form. | Chem. Form. 2-4a | — | 93 | 7 | — |
| | 1-1a (HFPMA) | (P2) | | | | |
| Ex. 13 | Chem. Form. | Chem. Form. 2-4a | Chem. Form. | 90 | 5 | 5 |
| | 1-1a (HFPMA) | (P2) | 6-1a | | | |
| Ex. 14 | Chem. Form. | Chem. Form. 2-3a | Chem. Form. | 90 | 5 | 5 |
| | 1-1a (HFPMA) | (M2) | 6-1a | | | |
| Ex. 15 | Chem. Form. | Chem. Form. 2-5a | Chem. Form. | 90 | 5 | 5 |
| | 1-1a (HFPMA) | (P2OH) | 6-1a | | | |
| Ex. 16 | Chem. Form. | Chem. Form. 2-8a | Chem. Form. | 90 | 5 | 5 |
| | 1-1a (HFPMA) | (HFAP) | 6-1a | | | |
| Ex. 17 | Chem. Form. | Chem. Form. 2-2a | — | 95 | 5 | — |
| | 1-1a (HFPMA) | (M-TMS) | | | | |
| Ex. 18 | Chem. Form. | Chem. Form. 2-2a | — | 90 | 10 | — |
| | 1-1a (HFPMA) | (M-TMS) | | | | |
| Ex. 19 | Chem. Form. | Chem. Form. 6-3a | — | 90 | 10 | — |
| | 1-1a (HFPMA) | (F2) | | | | |
| Ex. 20 | Chem. Form. | Chem. Form. 4-3a | — | 95 | 5 | — |
| | 1-1a (HFPMA) | (SA3) | | | | |
| Ex. 21 | Chem. Form. | Chem. Form. 4-3a | — | 90 | 10 | — |
| | 1-1a (HFPMA) | (SA3) | | | | |
| Ex. 22 | Chem. Form. | Chem. Form. 4-3a | — | 85 | 15 | — |
| | 1-1a (HFPMA) | (SA3) | | | | |
| Comp. | Chem. Form. | Chem. Form. 6-3a | — | 95 | 5 | — |
| Ex. 1 | 1-1a (HFPMA) | (F2) | | | | |

[Chemical Formula 1-1a] 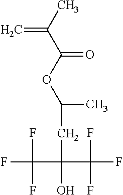
[Chemical Formula 2-2a] 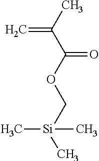
[Chemical Formula 2-3a] 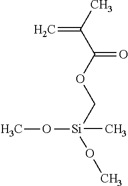
[Chemical Formula 2-4a] 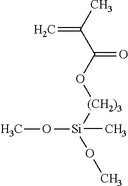
[Chemical Formula 2-5a] 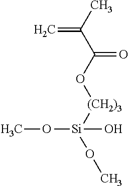
[Chemical Formula 2-6a] 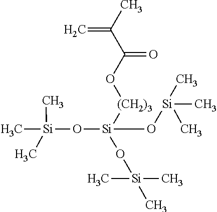
[Chemical Formula 2-8a] 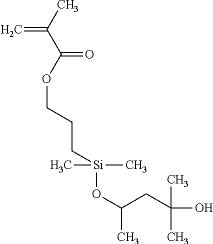
[Chemical Formula 4-3a]

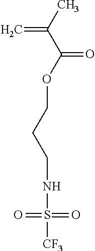

### EXAMPLES 23 TO 44

10 g of the polymers according to Examples 1 to 22 were mixed with 390 g of an organic solvent (4-methyl-2-pentenol:isoamylether=60:40 in weight ratio). This mixture was agitated for 4 hours, preparing a protective layer composition according to Examples 23 to 44.

### COMPARATIVE EXAMPLE 2

A protective layer composition was prepared according to the same method as Examples 23 to 44, except for using 10 g of the polymer according to Comparative Example 1.

Property Evaluation 1: Dissolution Speed Measurement

The protective layer compositions according to Examples 23 to 44 were measured regarding dissolution rate (DR) using RDA-760 (Litho Tech Japan Co.).

First, the protective layer compositions according to Examples 23 to 44 were respectively coated on a bare silicon wafer to be 40 nm thick, heat-treated at 110° C., and then cooled for about 1 minute, disposing a protective layer on the wafer.

The prepared wafer was measured regarding thickness using a thickness measurement device (K-MAC Co.). Then, the wafer was inserted in the RDA-760 including 2.38 wt % tetramethyl ammonium hydroxide (TMAH) (AZ EM Co. Ltd.) to measure its etching degree. After the measurement, the wafer was remeasured regarding thickness to calculate a difference between initial and later thicknesses. The development rate (DR) depending on time of each protective layer developed is provided in the following Table 2.

Property Evaluation 2: Contact Angle

Protective layer compositions according to Examples 23 to 44 were measured regarding contact angle using a DSA-100 (KRAUSS Co.) in the following method.

2-1. Static Contact Angle

3 ml of deionized water (DIW) was dripped on the wafer respectively including the top-coat layer. The wafer was measured regarding contact angle using DSA-100 (KRAUSS Co.). The measurement results are provided in the following Table 2.

2-2. Dynamic Contact Angle

The protective layer compositions of Examples 23 to 44 were respectively coated to be 40 nm thick on a bare silicon wafer, heat-treated at 110° C., and cooled to room temperature for 60 seconds, disposing a protective layer on the wafer.

45 μl of deionized water (DIW) was dripped on the wafer coated with each protective layer, and the wafer was tilted by a speed of 1°/sec to measure receding and advancing angles using DSA-100 (KRAUSS Co.). The results are provided in the following Table 2.

TABLE 2

| | | |
|---|---|---|
| | Dynamic contact | |
| Developing | angle (°) | Static |

| | rate | Receding | Advancing | contact |
|---|---|---|---|---|
| | (nm/s) | angle | angle | angle (°) |
| Comp. | 20 | 64.7 | 99 | 87 |
| Ex. 2 | | | | |
| Ex. 23 | 24.38 | 74.7 | 99.3 | 87.6 |
| Ex. 24 | 20.77 | 71.3 | 99.7 | 90.9 |
| Ex. 25 | 19.77 | 73.1 | 98.9 | 87.5 |
| Ex. 26 | 10.9 | 70.5 | 99.2 | 91.6 |
| Ex. 27 | 26.15 | 73.7 | 99.7 | 86.9 |
| Ex. 28 | 77.81 | 73.8 | 97.7 | 80.6 |
| Ex. 29 | 18.14 | 74.7 | 93.7 | 84.3 |
| Ex. 30 | 21.25 | 72.7 | 96.5 | 91.7 |
| Ex. 31 | 19.16 | 74.4 | 95.7 | 87.4 |
| Ex. 32 | 30.88 | 75 | 95.9 | 87.9 |
| Ex. 33 | 16.25 | 75.8 | 99 | 91.7 |
| Ex. 34 | 19.63 | 74.4 | 98.3 | 91.6 |
| Ex. 35 | 80 | 71.8 | 100 | 91.6 |
| Ex. 36 | 85.52 | 70.5 | 93.2 | 86.9 |
| Ex. 37 | 79.89 | 72.1 | 99.4 | 96.1 |
| Ex. 38 | 116.77 | 70.0 | 95.5 | 82.9 |
| Ex. 39 | 11.76 | 71.9 | 93 | 85.4 |
| Ex. 40 | 2.97 | 70.6 | 92.7 | 86.2 |
| Ex. 41 | 8.24 | 76.3 | 92.1 | 86.4 |
| Ex. 42 | 70.33 | 70.1 | 95 | 83.4 |
| Ex. 43 | 83.82 | 70.0 | 91.6 | 82.4 |
| Ex. 44 | 55.84 | 71.2 | 97.1 | 82.5 |

As shown in Table 2, a protective layer disposed using the protective layer compositions of Examples 23 to 44 had a receding angle of 70° or more, while the one of Comparative Example 2 had a receding angle of 64.7°, which is lower than 70°. Accordingly, the protective layer compositions according to Examples 23 to 44 had no water mark problem compared with the one of Comparative Example 2, since they were good at water washing. In addition, protective layers disposed using compositions of Examples 23 to 44 and Comparative Example 2 all had an advancing angle of 100° or less, so that water could be smoothly injected. Furthermore, the protective layers according to Examples 23 to 44 and Comparative Example 2 all had a high static contact angle, which shows they are very hydrophobic.

In general, a liquid immersion lithography method may have a problem, in that an acid-generator may be eluted from a resist layer when the resist layer directly contacts a liquid for liquid immersion lithography (such as water and the like) during the exposure. The eluted product may damage the lens, and may bring about difficulty in accomplishing a desired pattern or satisfactory resolution. In addition, when water used as a liquid for the liquid immersion lithography method has a low receding angle in a resist layer, the water may not be rapidly drained during the high speed scan exposure and thus may leave a water mark on the resist layer. In order to solve this problem, a method of using a particular photoresist resin for a liquid immersion lithography method, or adding an additive thereto, has been suggested. However, this may secure a sufficient receding angle of water against a the resist layer or sufficiently decrease an amount eluted into water.

In contrast, as described above, a polymer according to an embodiment may provide excellent productivity and fewer defects when regulating receding and advancing angles.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A polymer for a resist protective layer, comprising:
a first repeating unit represented by the following Chemical Formula 1; and
a second repeating unit including at least one repeating unit represented by the following Chemical Formulae 2 to 6: 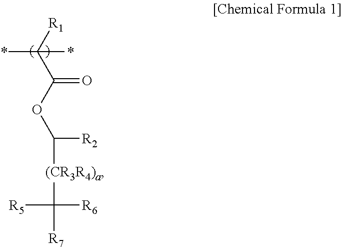
wherein, in Chemical Formula 1,
R₁ is hydrogen, fluorine, or a substituted or unsubstituted alkyl group,
R₂ is hydrogen or a substituted or unsubstituted alkyl group,
R₃ and R₄ are the same or different, and are hydrogen, fluorine, or a substituted or unsubstituted alkyl group,
R₅ to R₆ are the same or different, and are hydrogen or a fluoroalkyl group, provided that at least one R₅ to R₆ is —(CH₂)ₙ—CF₃ (n is 0 to 10),
R₇ is OH or SH, and
a is an integer ranging from 0 to 10, 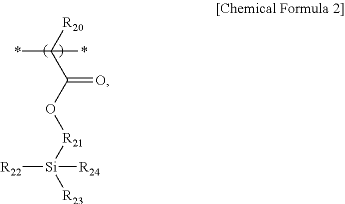
wherein, in Chemical Formula 2,
R₂₀ is hydrogen, fluorine, or a substituted or unsubstituted alkyl group,
R₂₁ is a single bond or an alkylene group, and
R₂₂ to R₂₄ are the same or different, and are hydrogen, fluorine, a substituted or unsubstituted alkyl group, OR₂₅, or OR₂₆OH, wherein R₂₅ and R₂₆ are the same or different, and are hydrogen, fluorine, a substituted or unsubstituted alkyl group, or Si(R₂₇)₃, wherein R₂₇ is hydrogen, fluorine, or a substituted or unsubstituted alkyl group, 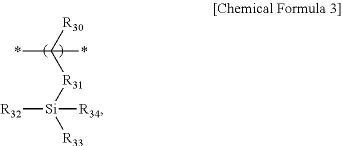
wherein, in Chemical Formula 3,
R₃₀ is hydrogen, fluorine, or a substituted or unsubstituted alkyl group,
R₃₁ is a single bond, or a substituted or unsubstituted alkylene group, and
R₃₂ to R₃₄ are the same or different, and are hydrogen, fluorine, a substituted or unsubstituted alkyl group, or OR₃₅, wherein R₃₅ is hydrogen, fluorine, a substituted or unsubstituted alkyl group, or Si(R₃₆)₃, wherein R₃₆ is hydrogen, fluorine, or a substituted or unsubstituted alkyl group, 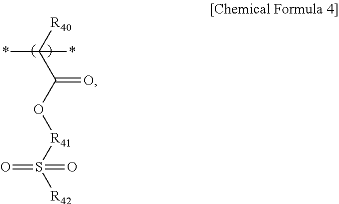
wherein, in Chemical Formula 4,
R₄₀ is hydrogen, fluorine, or a substituted or unsubstituted alkyl group,
R₄₁ is a single bond, or an alkylene group where carbon is partially replaced or not replaced with nitrogen, and
R₄₂ is a substituted or unsubstituted alkyl group or an OH group, 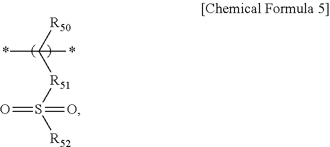
wherein, in Chemical Formula 5,
R₅₀ is hydrogen, fluorine, or a substituted or unsubstituted alkyl group,
R₅₁ is a single bond, or a linear, branched, or cyclic alkylene group where carbon is partially replaced or not replaced with nitrogen, and
R₅₂ is a substituted or unsubstituted alkyl group or an OH group, 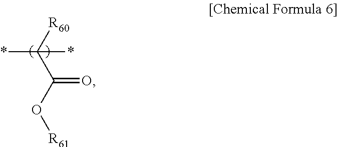
wherein, in Chemical Formula 6,
R₆₀ is hydrogen, fluorine, or a substituted or unsubstituted alkyl group, and
R₆₁ is hydrogen, a substituted or unsubstituted alkyl group, or a hydroxy alkyl group.

2. The polymer as claimed in claim 1, wherein the first repeating unit and the second repeating unit are present in the polymer at a ratio of about 95:5 to about 30:70 mol %.

3. The polymer as claimed in claim 1, wherein the polymer has a weight average molecular weight ranging from about 3,000 to about 50,000.

4. The polymer as claimed in claim 1, wherein the second repeating unit includes at least one repeating unit represented by Chemical Formula 2, the at least one repeating unit represented by Chemical Formula 2 being selected from the group represented by the following Chemical Formulae 2-1 to 2-8:

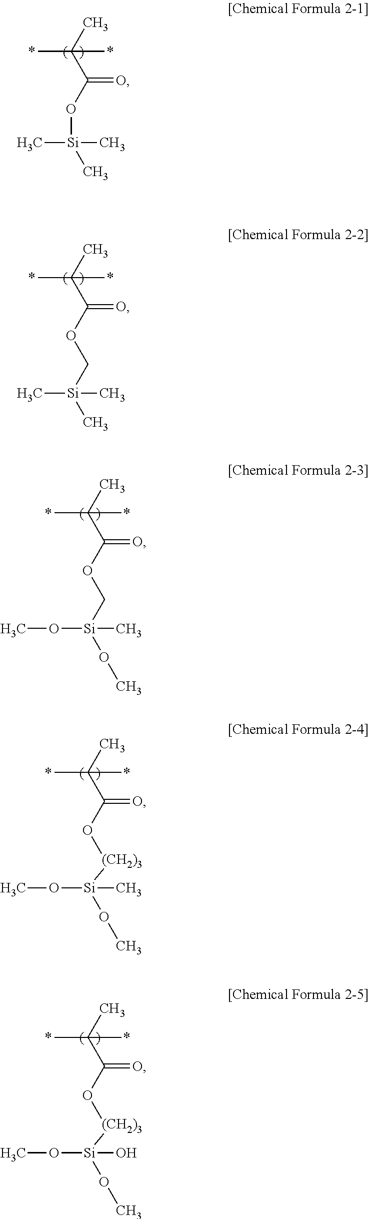

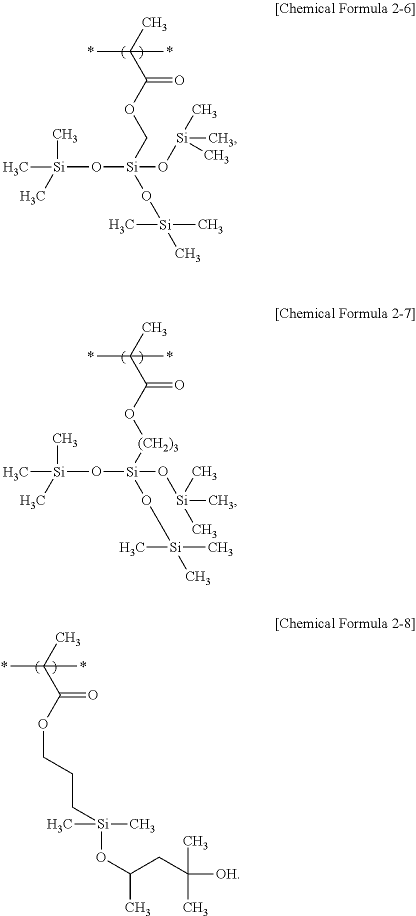

5. The polymer as claimed in claim 1, wherein the second repeating unit includes at least one repeating unit represented by Chemical Formula 3, the at least one repeating unit represented by Chemical Formula 3 being represented by the following Chemical Formula 3-1:

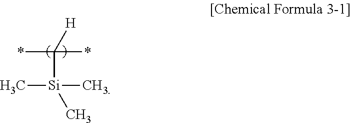

6. The polymer as claimed in claim 1, wherein the second repeating unit includes at least one repeating unit represented by Chemical Formula 4, the at least one repeating unit represented by Chemical Formula 4 being selected from the group represented by the following Chemical Formulae 4-1 to 4-3:

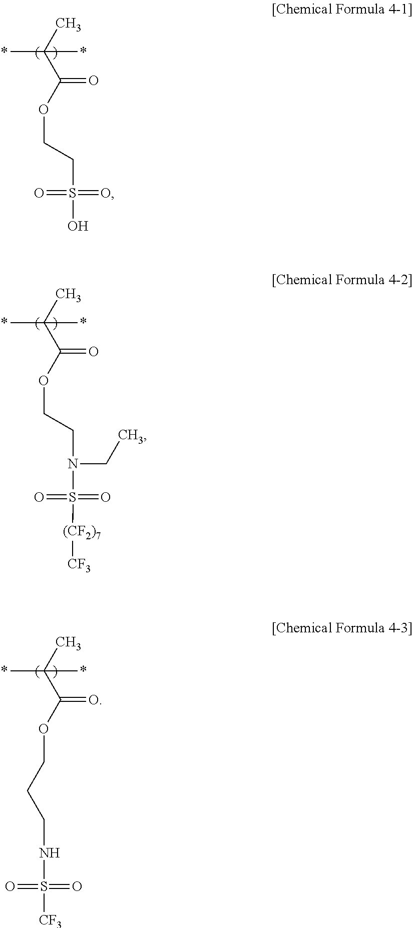

7. The polymer as claimed in claim 1, wherein the second repeating unit includes at least one repeating unit represented by Chemical Formula 5, the at least one repeating unit represented by Chemical Formula 5 being selected from the group represented by the following Chemical Formulae 5-1 to 5-2:

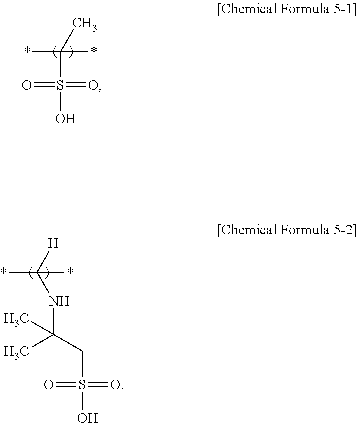

8. The polymer as claimed in claim 1, wherein the second repeating unit includes at least one repeating unit represented by Chemical Formula 6, the at least one repeating unit represented by Chemical Formula 6 being selected from the group represented by the following Chemical Formulae 6-1 to 6-3:

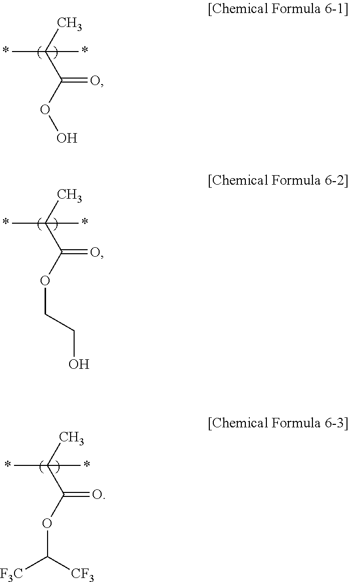

9. A resist protective layer composition, comprising:
a polymer as claimed in claim 1; and
an organic solvent.

10. The composition as claimed in claim 9, wherein the polymer is included in an amount of about 1 to about 30 parts by weight based on 100 parts by weight of the organic solvent.

11. The composition as claimed in claim 9, further comprising a photoacid generator.

12. A method of forming a pattern, the method comprising:
providing a photosensitive resin composition layer on a substrate;
providing a protective layer on the photosensitive resin composition layer using a protective layer composition as claimed in claim 9; and
forming a pattern using liquid immersion lithography using the photosensitive resin composition layer having the protective layer thereon.
